(19) United States
(12) Patent Application Publication
(10) Pub. No.: US 2026/0212820 A1
(43) Pub. Date: Jul. 23, 2026

(54) DISPLAY DEVICE

(71) Applicant: LG Display Co., Ltd., Seoul (KR)

(72) Inventor: Min Ji HAN, Paju-si (KR)

(73) Assignee: LG Display Co., Ltd., Seoul (KR)

(21) Appl. No.: 19/440,384

(22) Filed: Jan. 5, 2026

(30) Foreign Application Priority Data
Jan. 20, 2025 (KR) 10-2025-0008196

(51) Int. Cl. G09G 3/3233; H10K 59/121

(52) U.S. Cl. CPC G09G 3/3233; H10K 59/1213; G09G 2300/0426; G09G 2300/0819; G09G 2300/0842; G09G 2300/0861; G09G 2310/08

(57) ABSTRACT

A display device includes a light emitting element, a driving transistor including a first electrode connected to a first node, a first gate electrode connected to a second node, and a second electrode connected to a third node, a first switching transistor including a gate electrode to which a first scan signal is input, a first electrode connected to the second node, and a second electrode connected to the third node, a second switching transistor including a gate electrode to which a second scan signal is input, a first electrode connected to a data line to which a data voltage signal is applied, and a second electrode connected to the first node, and a capacitor connected between an input line of a high-potential voltage and the second node to store a data voltage compensated by a threshold voltage.

### CROSS-REFERENCE TO RELATED APPLICATION(S)

This application claims the benefit of Korean Patent Application No. 10-2025-0008196, filed on Jan. 20, 2025, which is hereby incorporated by reference as if fully set forth herein.

### BACKGROUND

### Technical Field

The present disclosure relates to a display device.

### Description of the Related Art

Electroluminescent displays have advantages of fast response speed, high luminous efficacy, and wide viewing angle, and thus have been widely used as display devices. Electroluminescent displays are divided into inorganic luminescent displays and organic luminescent displays according to a material of a luminescent layer. Each pixel of an electroluminescent display may include a self-luminous light emitting element and at least one transistor for driving the light emitting element.

Such an electroluminescent display displays an image based on light generated from the light emitting element, and thus has various advantages. However, in order to improve image quality, it is necessary to improve accuracy of a pixel driving circuit that controls light emission of the light emitting element.

### BRIEF SUMMARY

Accordingly, the present disclosure is directed to a display device that substantially obviates one or more problems due to limitations and disadvantages of the related art.

The embodiments disclosed in the present disclosure are intended to solve the above-mentioned problem, and provide a display device capable of improving accuracy of operation of a subpixel.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a display device includes a light emitting element, a driving transistor including a first electrode connected to a first node, a first gate electrode connected to a second node, and a second electrode connected to a third node, and configured to apply a voltage according to a data voltage signal applied to the first node to the second node during a threshold voltage sampling period, generate a driving current according to the voltage applied to the second node using a high-potential voltage applied to the first node during an emission period, and apply the driving current to the third node, a first switching transistor including a gate electrode to which a first scan signal is input, a first electrode connected to the second node, and a second electrode connected to the third node, a second switching transistor including a gate electrode to which a second scan signal is input, a first electrode connected to a data line to which the data voltage signal is applied, and a second electrode connected to the first node, and a capacitor unit connected between an input line of the high-potential voltage and the second node, wherein the capacitor unit, in operation, stores a data voltage compensated by a threshold voltage, wherein, in operation, capacitance of the capacitor unit is decreased during the threshold voltage sampling operation and is increased during the emission operation.

The capacitor unit may include a first capacitor including a first electrode connected to the second node and a second electrode connected to a fifth node, a second capacitor including a first electrode connected to the fifth node and a second electrode connected to the input line of the high-potential voltage, and a first switch configured to interconnect the first capacitor and the second capacitor during the threshold voltage sampling period, and to connect the fifth node to the input line of the high-potential voltage in a period other than the threshold voltage sampling period.

The first switch may include a gate electrode configured to receive the second scan signal, a first electrode connected to the input line of the high-potential voltage, and a second electrode connected to the fifth node, and the first switch may be turned on and off in synchronization with the second switching transistor.

The driving transistor may include a second gate electrode of a bottom gate, and the display device may further include a gate control circuit configured to connect the second gate electrode of the driving transistor to the second node during the threshold voltage sampling period.

The gate control circuit may include a second switch including a gate electrode configured to receive the second scan signal, a first electrode connected to the second node, and a second electrode connected to the second gate electrode of the driving transistor, and a third switch including a gate electrode configured to receive the second scan signal, a first electrode connected to the input line of the high-potential voltage, and a second electrode connected to the second gate electrode of the driving transistor, and the second switch may be turned on and off in synchronization with an on/off operation of the second switching transistor, and the third switch may be turned on and off opposite to the on/off operation of the second switching transistor.

The second switching transistor may include a P-type transistor, the second switch may include a P-type transistor, and the third switch may include an N-type transistor.

A semiconductor layer, a first metal layer, and a gate metal layer may be sequentially stacked on a light-shielding pattern, a first pattern configured to apply the high-potential voltage may be formed in the light-shielding pattern, the first node may be formed in the semiconductor layer, a second pattern configured to apply the high-potential voltage and a first metal first scan line pattern configured to transmit the first scan signal may be formed in the first metal layer, a gate metal first scan line pattern may be formed in the gate metal layer at a position overlapping the first metal first scan line pattern, and the first pattern may be formed to be extended more than the second pattern.

The first pattern may be formed to be extended from the semiconductor layer to an area where an active semiconductor layer is not formed.

A semiconductor layer, a first gate metal layer, a first metal layer, and a second gate metal layer may be sequentially stacked on a light-shielding pattern, a first pattern configured to apply the high-potential voltage may be formed in the light-shielding pattern, the first node may be formed in the semiconductor layer, a second scan line pattern configured to apply the first scan signal may be formed in the first gate metal layer, a second pattern configured to apply the high-potential voltage and a first metal first scan line pattern configured to transmit the first scan signal may be formed in the first metal layer, a gate metal first scan line pattern may be formed in the second gate metal layer at a position overlapping the first metal first scan line pattern, and the second scan line pattern, the first metal first scan line pattern, and the gate metal first scan line pattern may be formed to overlap in the same area.

The first pattern may be formed to be extended more than the second pattern.

Each of the driving transistor, the first switching transistor, and the second switching transistor may be a thin film transistor (TFT).

It is to be understood that both the foregoing general description and the following detailed description of the present disclosure are exemplary and explanatory and are intended to provide further explanation of the disclosure as claimed.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic block diagram of a display device;

FIG. 2 is a circuit diagram of a subpixel included in the display device;

FIG. 3 is a waveform diagram of a scan signal and an emission control signal of the subpixel of FIG. 2;

FIGS. 4 to 6 are diagrams illustrating a driving method in each driving period of the subpixel of FIG. 2;

FIGS. 7 to 9 are diagrams for describing a sampling error that occurs in the subpixel of FIG. 2;

FIGS. 10 and 11 are circuit diagrams for describing an error reduction structure of a subpixel according to a first embodiment of the present disclosure;

FIGS. 12 to 14 are circuit diagrams for describing an error reduction structure of a subpixel according to a second embodiment of the present disclosure;

FIGS. 15A, 15,B, 16A, and 16B are circuit diagrams for describing an error reduction structure of a subpixel according to a third embodiment of the present disclosure; and

FIGS. 17A, 17,B, 18A, and 18B are circuit diagrams for describing an error reduction structure of a subpixel according to a fourth embodiment of the present disclosure.

### DETAILED DESCRIPTION

Advantages and features of the present disclosure and a method of achieving the advantages and features will become clear with reference to the embodiments described in detail below together with the accompanying drawings. However, the present disclosure is not limited to the embodiments disclosed below and may be implemented in various different forms, and the present embodiments are provided only to make the disclosure of the present disclosure complete and to fully inform a person having ordinary skill in the art to which the present disclosure pertains of the scope of the invention.

The shapes, sizes, ratios, angles, numbers, etc., disclosed in the drawings to describe the embodiments of the present disclosure are illustrative, and thus the present disclosure is not limited to the illustrated matters. The same reference numerals refer to the same components throughout the specification. When the terms “include”, “have”, and “consist of”, etc., are used in the present disclosure, other parts may be added unless “only” is used. When a component is expressed in a singular form, this includes the case where the component is plural unless there is a specifically explicit description to the contrary.

When interpreting a component, the component is interpreted as including an error range even if there is no separate explicit description.

When describing a positional relationship, for example, when a positional relationship between two parts is described as “on”, “above”, “below”, “next to”, etc., one or more other parts may be located between the two parts, unless “immediately” or “directly” is used.

Even though the terms first, second, etc., may be used to describe various components, these components are not limited by these terms. These terms are only used to distinguish one component from another. Thus, a first component mentioned below may be a second component within the technical concept of the present disclosure.

In addition, each of a pixel circuit and a gate driver of a display device described below may include a plurality of transistors. The transistors may be implemented as an oxide thin film transistor (TFT) including an oxide semiconductor, an LTPS TFT including low temperature poly silicon (LTPS), etc. Each of the transistors may be implemented as a p-channel TFT or an n-channel TFT.

A transistor is a three-electrode device that includes a gate, a source, and a drain. The source is an electrode that supplies carriers to the transistor. Inside the transistor, carriers start to flow from the source. The drain is an electrode through which carriers exit the transistor. In the transistor, carriers flow from the source to the drain. In the case of an n-channel transistor, since the carriers are electrons, a source voltage is lower than a drain voltage so that electrons may flow from the source to the drain. In the n-channel transistor, current flows in a direction from the drain to the source. In the case of a p-channel transistor (PMOS), since the carriers are holes, the source voltage is higher than the drain voltage so that the holes may flow from the source to the drain. In the p-channel transistor, since holes flow from the source to the drain, current flows from the source to the drain. It should be noted that the source and the drain of the transistor are not fixed. For example, the source and the drain may be changed depending on the applied voltage. Therefore, the disclosure is not limited by the source and the drain of the transistor. In the following description, the source and the drain of the transistor will be referred to as first and second electrodes.

A gate signal swings between a gate-on-voltage and a gate-off-voltage. The gate-on-voltage is set to a voltage higher than a threshold voltage of the transistor, and the gate-off-voltage is set to a voltage lower than the threshold voltage of the transistor. The transistor turns on in response to the gate-on-voltage, and turns off in response to the gate-off-voltage. In the n-channel transistor, the gate-on-voltage may be a gate-high-voltage (VGH), and the gate-off-voltage may be a gate-low-voltage (VGL). In the p-channel transistor, the gate-on-voltage may be a VGL, and the gate-off-voltage may be a VGH.

Each pixel of an electroluminescent display device includes a light emitting element and a driving element that generates pixel current according to a voltage between a gate and a source to drive the light emitting element. The light emitting element includes an anode, a cathode, and an organic compound layer formed between these electrodes. The organic compound layer may include, but is not limited to, a hole injection layer (HIL), a hole transport layer (HTL), an emission layer (EML), an electron transport layer (ETL), an electron injection layer (EIL), etc. When a pixel current flows in the light emitting element, holes passing through the HTL and electrons passing through the ETL move to the EML, thereby forming excitons, and as a result, the EML may emit visible light.

Recently, there have been increasing attempts to implement some transistors included in the pixel circuit of the electroluminescent display device as oxide transistors. Oxide transistors use an oxide referred to as IGZO, which is a combination of In (indium), Ga (gallium), Zn (zinc), and O (oxygen), instead of polysilicon as a semiconductor material.

An oxide transistor has low off-current, and thus has an advantage of high driving stability and reliability during low-speed operation in which an off period of the transistor is relatively long. Therefore, the oxide transistor may be adopted by a large liquid crystal display device that requires high resolution and low power operation, or an OLED TV whose screen size is not suitable for a low-temperature polysilicon process.

The display device according to the present embodiment may be implemented as a television, a video player, a personal computer (PC), a home theater, an automobile electrical device, a smartphone, etc., but the present disclosure is not limited thereto. The display device according to an embodiment of the present disclosure may be implemented as a light emitting diode (LED) display, a quantum dot display (QDD) device, a liquid crystal display (LCD) device, etc. However, for convenience of description, a display device that directly emits light based on an inorganic light emitting diode or an organic light emitting diode is taken as an example below.

Throughout the specification, the same reference numerals refer to substantially the same components. Hereinafter, embodiments of the present disclosure will be described in detail with reference to the attached drawings. In the following description, when it is determined that a detailed description of a known function or configuration related to the present disclosure may unnecessarily obscure the gist of the present disclosure, the detailed description will be omitted.

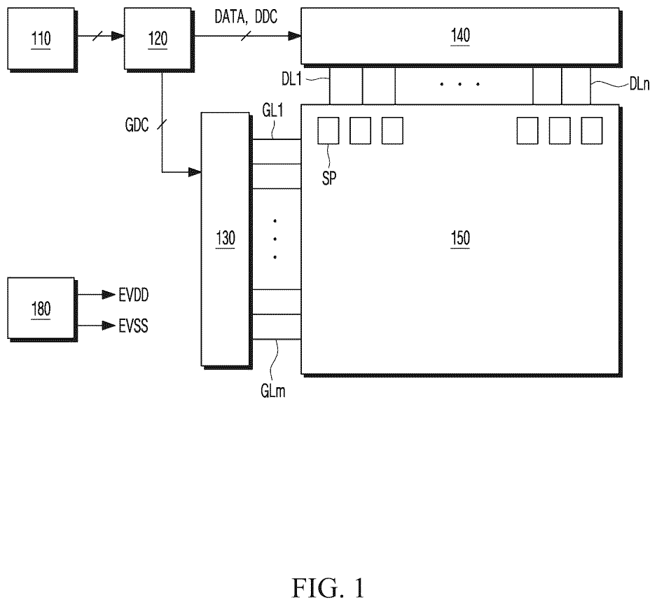

FIG. 1 is a block diagram schematically illustrating a configuration of a display device.

Referring to FIG. 1, the display device may include an image supply unit 110, a timing controller 120, a gate driver 130, a data driver 140, a display panel 150, a power supply 180, etc.

The image supply unit 110 may output various driving signals as well as an image data signal supplied from the outside or an image data signal stored in an internal memory. The image supply unit 110 may supply data signals and various driving signals to the timing controller 120. The image supply unit 110 may be any one of a TV (Television) system, a set-top box, a navigation system, a personal computer (PC), a home theater system, a mobile device, a wearable device, and a vehicle system.

In the display panel 150, a plurality of data lines DL1 to DLn and a plurality of gate lines GL1 to GLm intersect, and subpixels SP are arranged in a matrix at respective intersecting areas and each connected to a gate line GL and a data line DL. One subpixel SP may receive a gate signal from the gate driver 130 through the gate line GL and a data signal from the data driver 140 through the data line DL. Here, the gate line GL may supply a scan signal Scan and an emission control signal EM, and the data line DL may supply a data voltage Vdata. Each subpixel SP includes a light emitting element and a pixel circuit that controls the amount of current applied to an anode of the light emitting element. The pixel circuit may include a driving transistor that controls the amount of current so that a constant current may flow to the light emitting element. The light emitting element emits light during an emission period and does not emit light during a period other than the emission period. During periods other than the emission period, initialization of the pixel circuit, programming, reset of the light emitting element, etc., may be performed.

The timing controller 120 may output a gate timing control signal GDC for controlling the operation timing of the gate driver 130, a data timing control signal DDC for controlling the operation timing of the data driver 140, various synchronization signals (Vsync, which is a vertical synchronization signal, and Hsync, which is a horizontal synchronization signal), etc. The timing controller 120 may supply a data signal DATA supplied from the image supply unit 110 together with the data timing control signal DDC to the data driver 140. The timing controller 120 may be formed as an IC (Integrated Circuit) and mounted on a printed circuit board, but the present disclosure is not limited thereto.

The data driver 140 may sample and latch the data signal DATA in response to the data timing control signal DDC supplied from the timing controller 120, convert a digital data signal into an analog data voltage based on a gamma reference voltage, and output the analog data voltage. The data driver 140 may supply a data voltage to subpixels included in the display panel 150 through data lines DL1 to DLn. The data driver 140 may be formed as an IC and mounted on the display panel 150 or on a printed circuit board, but the present disclosure is not limited thereto.

The gate driver 130 may output a scan signal and an emission signal in response to the gate timing control signal GDC supplied from the timing controller 120. The gate driver 130 may supply at least one scan signal and an emission signal to subpixels SP included in the display panel 150 through the gate lines GL1 to GLm. The gate driver 130 may be formed as an IC or may be formed directly on the display panel 150 in a gate-in-panel manner.

The power supply 180 may convert power supplied from the outside into power required for driving the display device and output the power under the control of the timing controller 120. For example, the power supply 180 may convert power supplied from the outside into a high-potential voltage EVDD, a low-potential voltage EVSS, etc., and output the power, and may generate and output a voltage required for driving the gate driver 130 or a voltage required for driving the data driver 140.

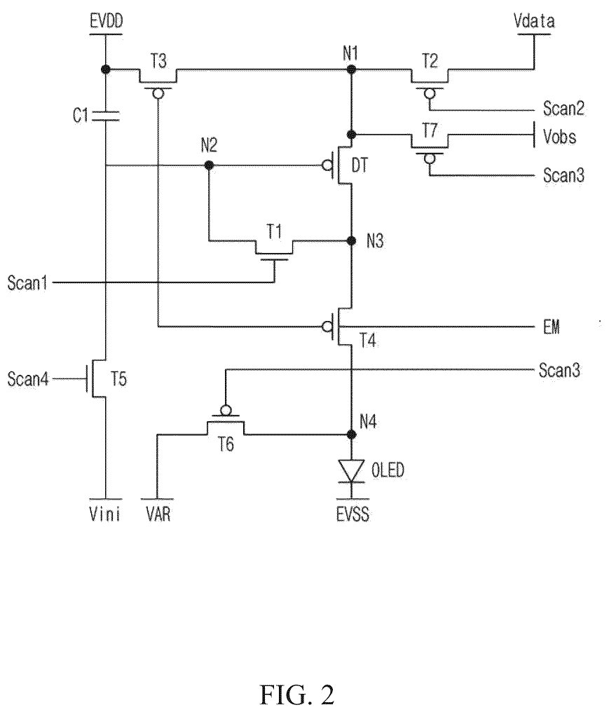

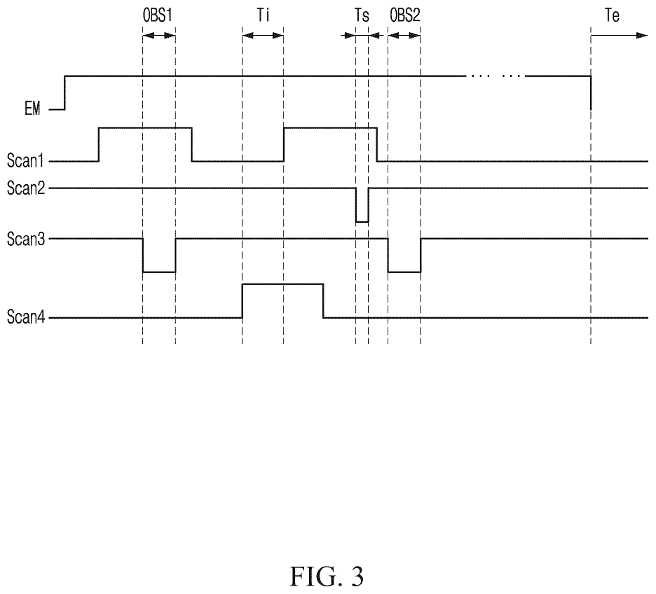

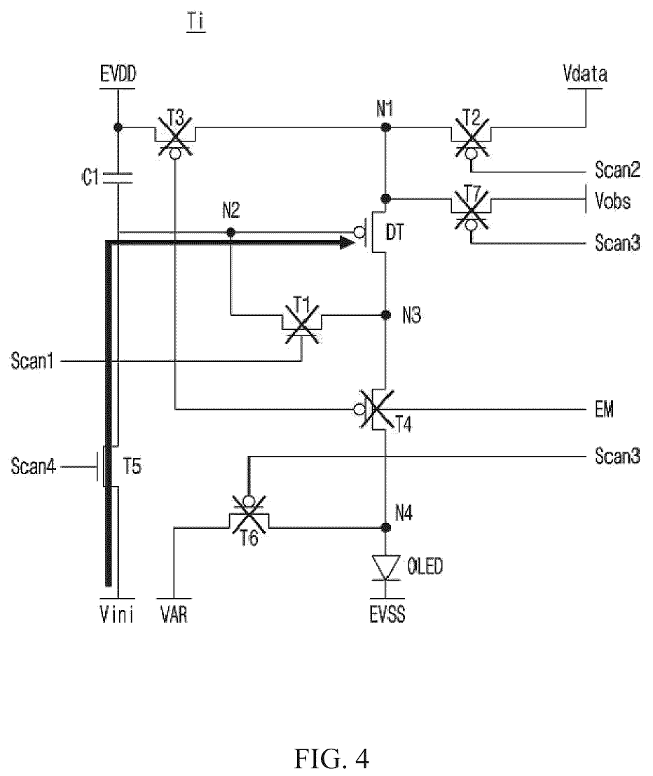

FIG. 2 is a circuit diagram of a subpixel included in the display device. FIG. 3 is a waveform diagram of a scan signal and an emission control signal of the subpixel of FIG. 2. FIGS. 4 to 6 are diagrams illustrating a driving method in each driving period of the subpixel of FIG. 2.

Referring to FIG. 2, one subpixel SP may be supplied with the high-potential voltage EVDD, the low-potential voltage EVSS, an initialization voltage Vini, an on-bias stress (OBS) voltage Vobs, and an anode reset voltage VAR, and may receive first to fourth scan signals Scan1 to Scan4, an emission signal EM, and a data voltage signal Vdata.

One subpixel SP may include an OLED (Organic Light Emitting Diode), a driving TFT DT, a first capacitor C1, and first to seventh switching TFTs T1 to T7. Each TFT of the subpixel SP may be configured as a p-type MOSFET (PMOS) or an n-type MOSFET (NMOS). In the present embodiment, a description will be given using an example in which the first switching TFT T1 and the fifth switching TFT T5 are implemented as n-type, and the remaining switching TFTs T2 to T4, and T6 to T7 and the driving TFT DT are implemented as p-type. Therefore, the first switching TFT T1 and the fifth switching TFT T5 are turned on when a high voltage is applied to the gate electrode, and the remaining switching TFTs T2 to T4, and T6 to T7 and the driving TFT DT are turned on when a low voltage is applied to the gate electrode.

According to an embodiment of the present disclosure, in a subpixel circuit, the first transistor T1 may function as a compensation transistor, the second transistor T2 may function as a data supply transistor, the third and fourth transistors T3 and T4 may function as emission control transistors, the fifth transistor T5 may function as an initialization transistor, the sixth transistor T6 may function as an anode reset transistor, and the seventh transistor T7 may function as an on-bias transistor.

The OLED emits light by a driving current supplied from the driving TFT DT. An anode of the OLED may be connected to a fourth node N4, and a cathode of the OLED may be connected to a wire to which the low-potential voltage EVSS is provided.

The driving TFT DT may have a gate electrode connected to a second node N2, a first electrode connected to a first node N1, and a second electrode connected to a third node N3. The driving TFT DT may generate a driving current supplied to the OLED based on a voltage of the second node N2. The driving TFT DT may be formed as a four-terminal transistor having a dual gate electrode. When the driving TFT DT is a four-terminal transistor, a top gate may be connected to the second node N2, and a bottom gate may be in contact with VDD. A structure of the four-terminal transistor will be described in more detail later.

The first capacitor C1 has one electrode connected to the second node N2 to which the gate electrode of the driving TFT DT is connected, and the other electrode connected to the input line of the high-potential voltage EVDD. The first capacitor C1 may store a data voltage for a certain period of time and provide the data voltage to the OLED. The first capacitor C1 may function as a storage capacitor.

The first switching TFT T1 may be turned on in response to a first scan signal Scan1. When the first switching TFT T1 is turned on, the second node N2 and the third node N3 may be interconnected. Accordingly, the gate electrode and a second electrode, which is a drain electrode, of the driving TFT DT, are interconnected so that the driving TFT DT may be switched to a diode-connected state. The first switching TFT T1 may include a gate electrode connected to the input line of the first scan signal Scan1, a first electrode connected to the second node N2, and a second electrode connected to the third node N3. The first switching TFT T1 may be an NMOS and may be implemented as an oxide TFT to have a low off-current and minimize leakage current during a turn-off period. Accordingly, the first switching TFT T1 is turned on in response to the first scan signal Scan1 at a high level, which is a turn-on voltage, and may sample a threshold voltage Vth of the driving TFT DT by diode-connecting the second node N2 and the third node N3. This first switching TFT T1 may be a compensation transistor.

The second switching TFT T2 may be turned on in response to the second scan signal Scan2. When the second switching TFT T2 is turned on, the data voltage signal Vdata is applied to the first node N1, which is the first electrode of the driving TFT DT. The second switching TFT T2 may include a gate electrode connected to an input line of the second scan signal Scan2, a first electrode connected to a data line to which the data voltage signal Vdata is supplied, and a second electrode connected to the first node N1. The second switching TFT T2 may apply the data voltage signal Vdata supplied from the data line to the first node N1, which is the first electrode of the driving TFT DT, in response to the second scan signal Scan2 at a low level, which is a turn-on voltage. The second switching TFT T2 may be a data supply transistor.

A control operation is performed to simultaneously turn on/off the third switching TFT T3 and the fourth switching TFT T4 according to the emission signal EM simultaneously input to respective gate electrodes thereof. The third switching TFT T3 and the fourth switching TFT T4 may control whether the OLED emits light. The third switching TFT T3 may have a first electrode connected to the input line of the high-potential voltage EVDD and a second electrode connected to the first node N1. The third switching TFT T3 may serve to transmit the high-potential voltage EVDD to the first electrode of the driving TFT DT in response to the emission signal EM. The fourth switching TFT T4 may have a first electrode connected to the third node N3 and a second electrode connected to the fourth node N4. The fourth switching TFT T4 may serve to transmit the driving current to the anode of the OLED in response to the emission signal EM. The third switching TFT T3 and the fourth switching TFT T4 may be emission control transistors.

The fifth switching TFT T5 may be turned on in response to the fourth scan signal Scan4. The fifth switching TFT T5 is turned on to apply the initialization voltage Vini to the second node N2, which is the gate electrode of the driving TFT DT. The fifth switching TFT T5 may include a gate electrode connected to the input line of the fourth scan signal Scan4, a first electrode connected to the input line of the initialization voltage Vini, and a second electrode connected to the second node N2. The fifth switching TFT T5 may initialize the gate electrode of the driving TFT DT by applying the initialization voltage Vini to the second node N2, which is the gate electrode of the driving TFT DT, in response to the fourth scan signal Scan4 at a high level, which is a turn-on voltage. The fifth switching TFT T5 may be an initialization transistor.

The sixth switching TFT T6 may be turned on in response to the third scan signal Scan3. The sixth switching TFT T6 is turned on to apply the anode reset voltage VAR to the anode of the OLED. The sixth switching TFT T6 may include a gate electrode connected to the input line of the third scan signal Scan3, a first electrode connected to the input line of the anode reset voltage VAR, and a second electrode connected to the fourth node N4. The sixth switching TFT T6 may apply the anode reset voltage VAR to the anode of the OLED in response to the third scan signal Scan3 at a low level, which is a turn-on voltage. The sixth switching TFT T6 may be an anode reset transistor.

The seventh switching TFT T7 may be turned on in response to the third scan signal Scan3. The seventh switching TFT T7 is turned on to apply the OBS voltage Vobs to the first electrode of the driving TFT DT. The seventh switching TFT T7 may include a gate electrode connected to the input line of the third scan signal Scan3, a first electrode connected to the input line of the OBS voltage Vobs, and a second electrode connected to the first node N1. The seventh switching TFT T7 may apply the OBS voltage Vobs to the first electrode of the driving TFT DT in response to the third scan signal Scan3 at a low level, which is a turn-on voltage. The seventh switching TFT T7 may be an on-bias transistor.

FIG. 3 is a drawing describing operation of the scan signal and the emission control signal of the subpixel of FIG. 2. FIGS. 4 to 6 are drawings showing a driving method in each driving period of the subpixel of FIG. 2.

Referring to FIG. 3, the driving period of the subpixel may include an initialization period Ti, a sampling period Ts, an emission period Te, and at least one bias period OBS1 and OBS2. The initialization period T1 and the sampling period Ts may be performed during a non-emission period in which the emission signal EM is applied at an off level. During this non-emission period, a plurality of OBS operations may be performed.

During the first bias period OBS1, the first scan signal Scan1 and the third scan signal Scan3 are applied at the on level. In response to the first scan signal Scan1 being applied at a high voltage, which is the on level, the first switching TFT T1 is turned on, so that the second node N2 and the third node N3 may be interconnected to interconnect the gate electrode and the drain electrode, which is the second electrode, of the driving TFT DT. In response to the third scan signal Scan3 being applied at a low voltage, which is the on level, the seventh switching TFT T7 is turned on, so that the bias voltage Vobs may be applied to the first electrode of the driving TFT DT. In response to the third scan signal Scan3 being applied at a low voltage, which is the on level, the sixth switching TFT T6 is turned on, so that the anode reset voltage VAR may be applied to the anode of the OLED.

Referring to FIGS. 3 and 4, the pixel driving circuit may operate by including the initialization period Ti. The initialization period Ti is a period in which the voltage of the second node N2 to which the gate electrode of the driving transistor DT is connected is initialized.

During the initialization period Ti, the fourth scan signal Scan4 is applied at the on level. In response to the fourth scan signal Scan4 being applied at a high voltage, which is the on level, the fifth switching TFT T5 is turned on to apply the initialization voltage Vini to the second node N2, which is the gate electrode of the driving TFT DT. Accordingly, the gate electrode of the driving TFT DT may be initialized to the initialization voltage Vini.

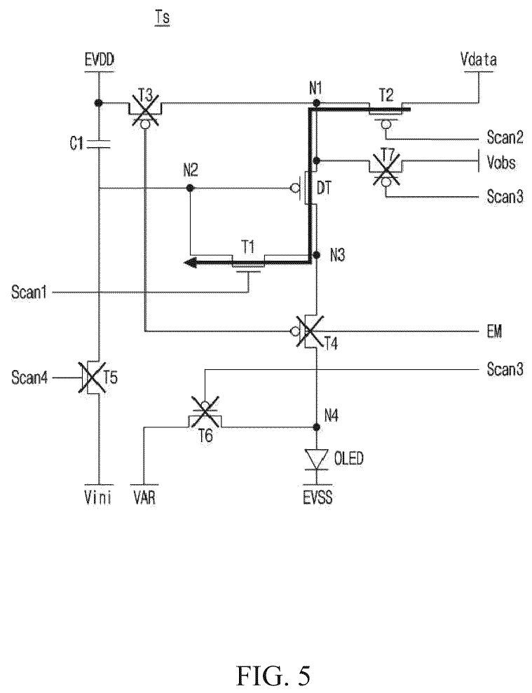

Referring to FIGS. 3 and 5, the pixel driving circuit may operate including the sampling period Ts. The sampling period Ts is a period in which the threshold voltage Vth of the driving TFT DT is sampled and the data voltage Vdata is programmed. During the sampling period Ts, the first scan signal Scan1 and the second scan signal Scan2 are applied at the on level. In response to the first scan signal Scan1 being applied at a high voltage, which is the on level, the first switching TFT T1 is turned on, so that the driving TFT DT may be diode-connected. In response to the second scan signal Scan2 being applied at a low voltage, which is the on level, the second switching TFT T2 is turned on, so that the data voltage signal Vdata is applied to the first node N1, which is the first electrode of the driving TFT DT. Since the data voltage signal Vdata is applied to the first node N1 of the driving TFT DT in a diode-connected state, the second node N2 is charged with a voltage Vdata−|Vth| corresponding to a difference between the data voltage Vdata and the threshold voltage Vth of the driving TFT DT by a current flowing from the source electrode to the drain electrode. Accordingly, when the sampling period Ts is completed, the threshold voltage Vth may be sampled at the first capacitor C1.

During the second bias period OBS2, the third scan signal Scan3 is applied at the on level. In response to the third scan signal Scan3 being applied at a low voltage, which is the on level, the seventh switching TFT T7 is turned on, so that the bias voltage Vobs may be applied to the first electrode of the driving TFT DT. In response to the third scan signal Scan3 being applied at a low voltage, which is the on level, the sixth switching TFT T6 is turned on, so that the first anode reset voltage VAR1 may be applied to the anode of the OLED.

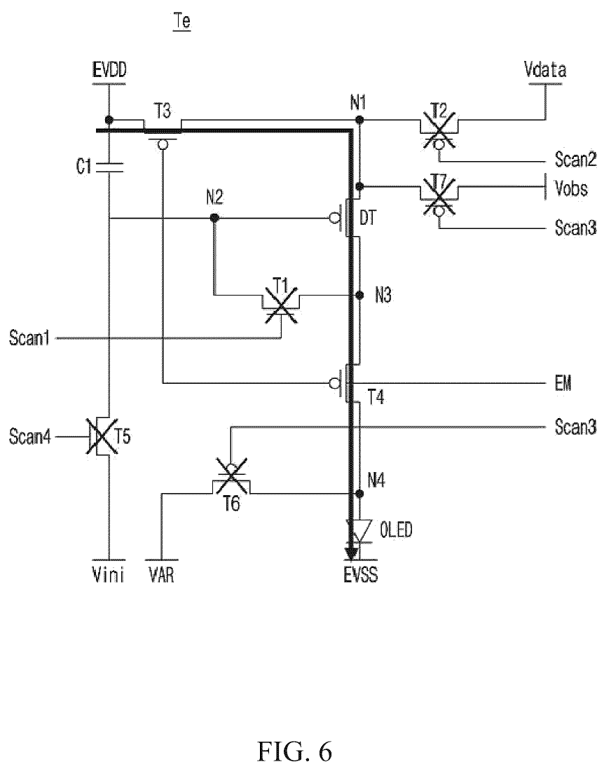

Referring to FIGS. 3 and 6, the emission period Te is a period in which the OLED is made to emit light with a driving current corresponding to the sampled data voltage with the sampled threshold voltage Vth offset.

During the emission period Te, the emission signal EM is applied at the on level. In response to the emission signal EM being applied at a low voltage, which is the on level, the third switching TFT T3 and the fourth switching TFT T4 are simultaneously turned on. When the third switching TFT T3 and the fourth switching TFT T4 are turned on, the first electrode of the driving TFT DT may be connected to the input line of the high-potential voltage EVDD, and the second electrode may be connected to the anode of the OLED. Accordingly, the driving TFT DT may apply a driving current corresponding to the data voltage to the OLED to cause the OLED to emit light.

As described above, a subpixel having a configuration such as that of FIG. 2 may sample a threshold voltage Vth during the sampling period Ts and cause the OLED to emit light with a driving current corresponding to the data voltage Vdata compensated by the threshold voltage Vth during the emission period Te. Therefore, in order to improve driving accuracy of the subpixel, a method of reducing an error occurring during sampling may be sought.

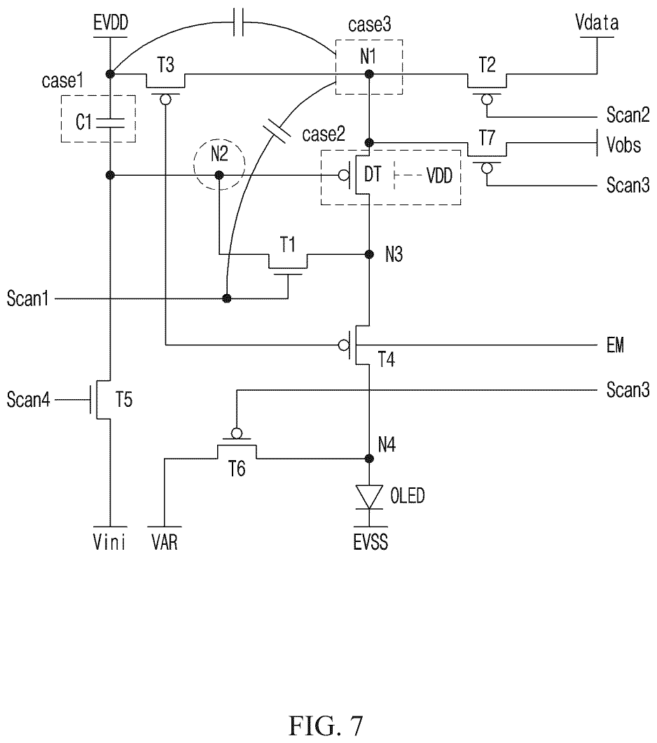

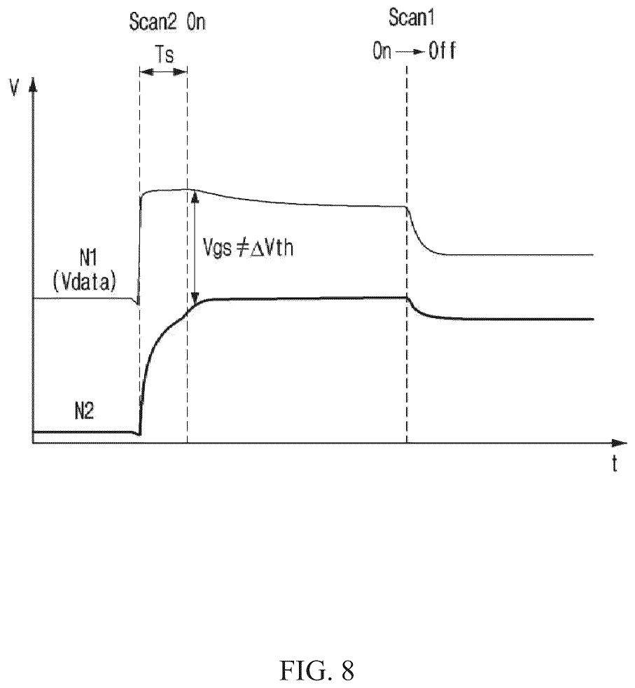

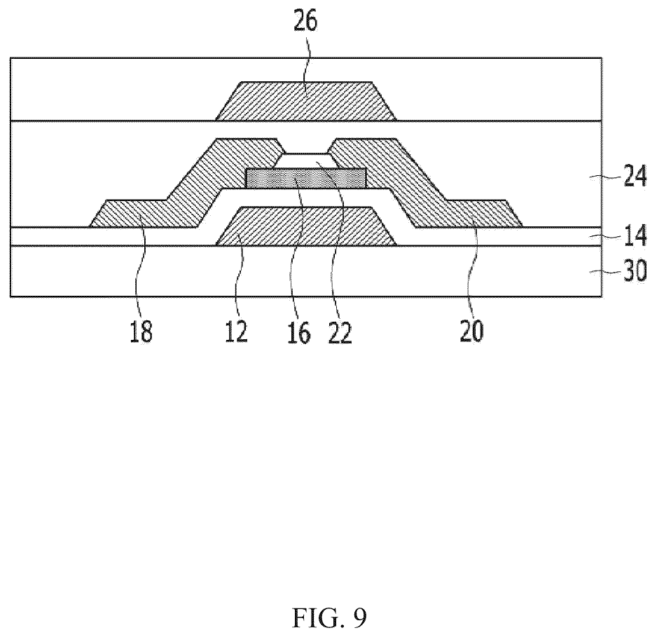

FIG. 7 and FIG. 8 are diagrams for describing a sampling error occurring in the subpixel of FIG. 2. FIG. 7 is a diagram illustrating an area where the sampling error occurs in the subpixel, FIG. 8 is a diagram illustrating voltage change of the first node N1 and the second node N2 during sampling, and FIG. 9 is a diagram illustrating a structure of the four-terminal TFT of FIG. 2.

As described above, during the sampling period Ts, the first scan signal Scan1 and the second scan signal Scan2 are applied at the on level, so that the first switching TFT T1 and the second switching TFT T2 are turned on. When the first switching TFT T1 is turned on, the driving TFT DT is diode-connected, and the switching TFT T2 is turned on, so that the data voltage signal Vdata is applied to the first node N1, which is the first electrode of the driving TFT DT.

Referring to FIG. 8, when the second scan signal Scan2 is applied at the on level (Scan2 On), the voltage of the first node N1 may rise to the voltage of the data voltage signal Vdata. Since the driving TFT DT is diode-connected, when the data voltage signal Vdata is applied to the first node N1, a current Ids flows between the source and the drain. The second node N2 is charged with the voltage Vdata-|Vth| corresponding to the difference between the data voltage Vdata and the threshold voltage Vth of the driving TFT DT by the current flowing from the source electrode to the drain electrode. Therefore, a voltage difference Vgs between the first node N1 and the second node N2 is maintained at ΔVth, which is the threshold voltage of the driving TFT DT, and when the first scan signal Scan1 and the second scan signal Scan2 are switched to an off state (Scan1 On→Off), the voltage Vdata−|Vth| of the second node N2, i.e., the data voltage compensated by the threshold voltage, may be maintained by the first capacitor C1.

However, in reality, in the subpixel, the voltage difference Vgs between the first node N1 and the second node N2 may be different from the threshold voltage ΔVth of the driving TFT DT (Vgs≠ΔVth), or a sampling error may occur in which an error occurs in the data voltage Vdata-|Vth compensated by the threshold voltage stored and maintained in the first capacitor C1.

In the first case (case 1), a sampling error may occur due to the capacitance of the first capacitor C1. The first capacitor C1 needs to be able to hold the voltage of the second node N2 at Vdata−|Vth| during the emission period Te. Since the holding characteristic is more advantageous when the capacitance is larger, the first capacitor C1 is designed to have a larger capacitance than a specific value. On the other hand, since the sampling error increases as the capacitance increases, an error may occur when the threshold voltage Vth is sampled.

In the second case (case 2), a sampling error may occur due to change in the driving characteristic of the driving TFT DT. The driving TFT DT formed on the display panel is a four-terminal transistor, and the bottom gate is in contact with VDD. Referring to FIG. 9, which illustrates the structure of the four-terminal transistor, the four-terminal transistor may include a bottom gate electrode 12, a top gate electrode 26, a first electrode 18, and a second electrode 20. It is possible to include a bottom gate electrode 12 formed on a substrate 30, a gate insulating film 14 formed on the bottom gate electrode 12, a first electrode 18 formed on the gate insulating film 14, and a second electrode 20 formed spaced apart from the first electrode 18. A semiconductor layer 16 forming a channel is formed between the first and second electrodes 18 and 20, and it is possible to include an etch stopper 22 formed on the semiconductor layer 16 to protect the semiconductor layer 16, an interlayer insulating film 24 covering the entire surface of the substrate 30 including the first and second electrodes 18 and 20 and the etch stopper 22, and a top gate electrode 26 formed on the interlayer insulating film 24 to face the bottom gate electrode 12. Here, the bottom gate electrode 12 may be formed using a bottom shield metal (BSM). When a voltage applied to the BSM is the same as a voltage VGS between the top gate and the source, operating characteristics of the driving TFT DT are not affected. However, when a voltage applied to the BSM is different from the voltage VGS between the top gate and the source, formation of a current channel is affected, causing the operating characteristics of the driving TFT DT, such as the threshold voltage Vth, to fluctuate. When the bottom gate of the driving TFT DT is in contact with VDD, Vgs of the bottom gate has a smaller value than Vgs of the top gate at the time of sampling. For example, Vgs of the bottom gate is at a level of −2 V to 3 V, and Vgs of the top gate is at a level of −8 V to −3 V, and thus the operating voltages are different. In this way, an error may occur when sampling the threshold voltage Vth due to a difference in operating voltage, i.e., Vgs, between the bottom gate and the top gate.

In the third case (case 3), when the first scan signal Scan1 is turned off after sampling the threshold voltage Vth, the voltage of the first node N1 fluctuates due to a kickback phenomenon, which may cause an error during sampling.

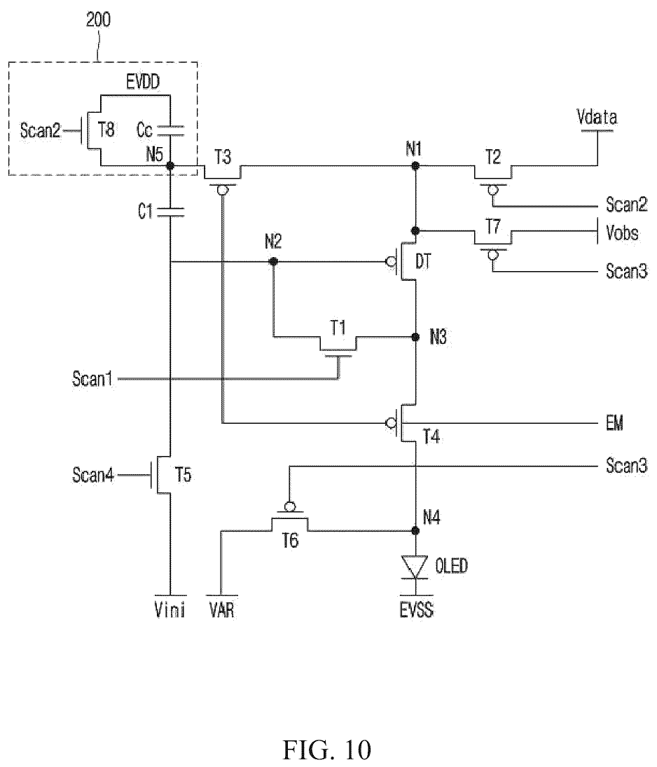

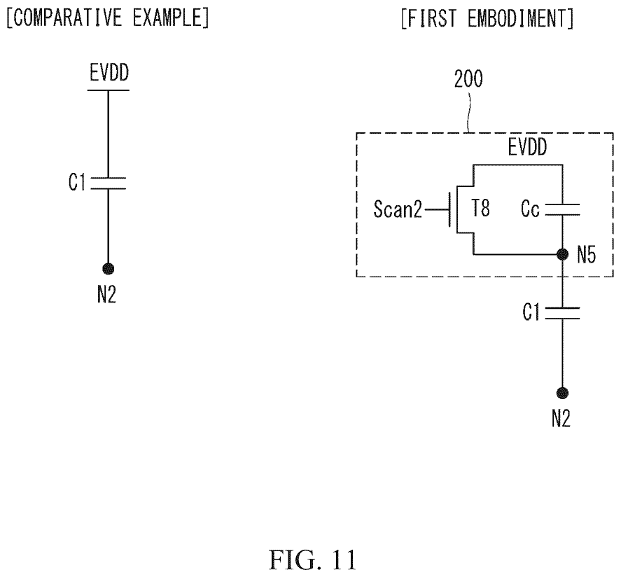

FIGS. 10 and 11 are circuit diagrams for describing an error reduction structure of the subpixel according to the first embodiment of the present disclosure. The error reduction structure of the subpixel according to the first embodiment of the present disclosure may reduce a sampling error that occurs due to the large capacitance of the first capacitor C1 when sampling the threshold voltage Vth, as described in the first case (case 1).

The subpixel circuit according to the first embodiment of the present disclosure has a difference from the subpixel of FIG. 2 in that the subpixel circuit includes a multi-capacitor circuit 200 in the connection line between the first capacitor C1 and the input line of the high-potential voltage EVDD. Since the other configurations perform the same function as that of the subpixel of FIG. 2, only different configurations will be described in detail in the following description.

The multi-capacitor circuit 200 according to the first embodiment may include a second capacitor Cc and an eighth switching TFT T8.

The second capacitor Cc has one electrode connected to the input line of the high-potential voltage EVDD and the other electrode connected to a fifth node N5 to which the first capacitor C1 is connected. Accordingly, the first capacitor C1 and the second capacitor Cc may be connected in series.

The eighth switching TFT T8 may be turned on in response to the second scan signal Scan2. The eighth switching TFT T8 may include a gate electrode connected to the input line of the second scan signal Scan2, a first electrode connected to the input line of the high-potential voltage EVDD, and a second electrode connected to the fifth node N5. Accordingly, the eighth switching TFT T8 may be connected in series with the first capacitor C1 and in parallel with the second capacitor Cc.

The second capacitor Cc and the eighth switching TFT T8 may be connected in parallel between the input line of the high-potential voltage EVDD and the fifth node N5, so that when the eighth switching TFT T8 is turned on, the high-potential voltage EVDD may be applied to the fifth node N5, and when the eighth switching TFT T8 is turned off, the second capacitor Cc may be connected between the input line of the high-potential voltage EVDD and the fifth node N5.

When the eighth switching TFT T8 is turned on, the high-potential voltage EVDD is applied to the fifth node N5. Accordingly, a voltage between both ends of the second capacitor Cc is set to the same as the high-potential voltage EVDD, and thus the capacitance by the second capacitor Cc becomes 0. Accordingly, as in the circuit of [Comparative Example] of FIG. 11, only the first capacitor C1 operates, and thus operation may be similar to that of the subpixel of FIG. 2.

When the eighth switching TFT T8 is turned off, the second capacitor Cc may be connected between the input line of the high-potential voltage EVDD and the fifth node N5. Accordingly, as in the circuit of [First Embodiment] of FIG. 9, the first capacitor C1 and the second capacitor Cc may be connected in series. When two capacitors are connected in series, total capacitance Total CST may be calculated as reciprocal of the sum of reciprocals of the capacitances CST1 and CST2 of the two capacitors, as in the following <Mathematical Formula>.

$$Total CST = \frac{C S T 1 * C S T 2}{C S T 1 + C S T 2} \qquad 〈 Mathematical Formula 〉$$

As can be seen from the above mathematical formula, when the first capacitor C1 and the second capacitor Cc are connected in series, the resultant capacitance is smaller than the capacitance of each capacitor.

When sampling the threshold voltage Vth of the driving TFT DT, it is advantageous to apply the smallest possible capacitance in order to shorten a sampling time and reduce sampling errors. Accordingly, the eighth switching TFT T8 may be set to be turned off only during the sampling period. For example, the eighth switching TFT T8 may receive the same scan signal, i.e., the second scan signal Scan2, as that of the second switching TFT T2 turned on only during the sampling period to apply the data voltage signal Vdata, and be provided as a TFT of a type opposite to that of the second switching TFT T2 so as to perform an on/off operation in the opposite manner to that of the second switching TFT T2. For example, an n-type TFT turned off when the second scan signal Scan2 input to the gate electrode is a low signal may be applied to the eighth switching TFT T8.

The subpixel circuit according to the first embodiment of the present disclosure may add the second capacitor Cc connected in series with the first capacitor C1 when sampling the threshold voltage Vth to reduce the capacitance, thereby reducing the sampling errors.

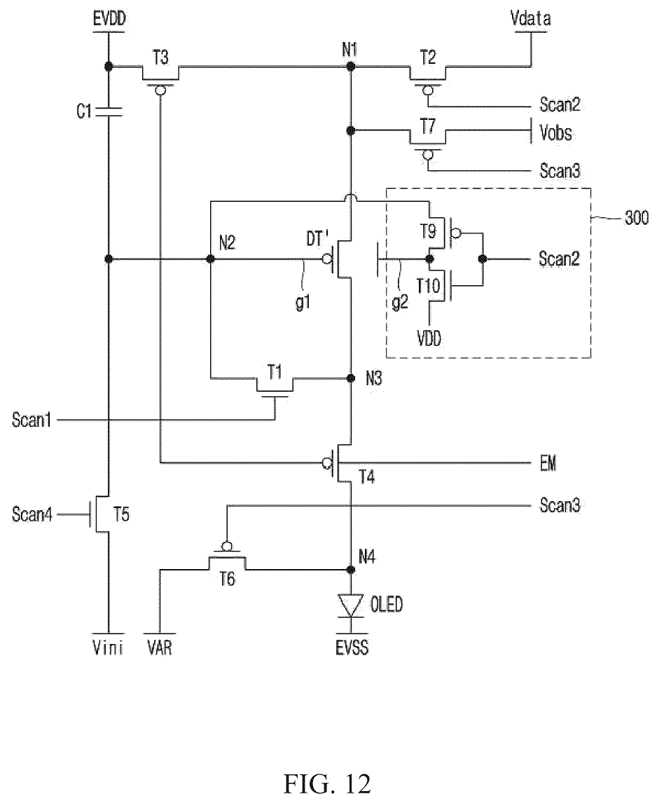

FIGS. 12 to 14 are circuit diagrams for describing an error reduction structure of the subpixel according to the second embodiment of the present disclosure. The error reduction structure of the subpixel according to the second embodiment of the present disclosure may reduce the sampling errors that occur due to change in the driving characteristics of the driving TFT DT described in the second case (case 2).

The subpixel circuit according to the second embodiment of the present disclosure is different from the subpixel of FIG. 2 in that the subpixel circuit includes a dual gate control circuit 300 that controls a bottom gate of a driving TFT DT′. Since the other configurations perform the same function as that of the subpixel of FIG. 2, only different configurations will be described in detail in the following description.

Referring to FIG. 12, in the subpixel circuit according to the second embodiment, the driving TFT DT′ is provided as a four-terminal transistor. A first gate electrode g1, which is a top gate of the driving TFT DT′, is connected to a second node N2. A second gate electrode g2, which is the bottom gate, may be controlled by the dual gate control circuit 300.

The dual gate control circuit 300 may interconnect the second gate electrode g2 to the first gate electrode g1 so that Vgs of the bottom gate and Vgs of the top gate may be maintained the same as each other when sampling the threshold voltage Vth. In the case of a period other than a period of sampling the threshold voltage Vth, the dual gate control circuit 300 may prevent the threshold voltage Vth of the driving TFT DT′ from changing by connecting the second gate electrode g2, which is the bottom gate, to the input line of VDD. Here, VDD and EVDD have the same level of voltage supplied from the same power source.

The dual gate control circuit 300 may be controlled by the same scan signal, i.e., the second scan signal Scan2, as that of the second switching TFT T2, which is turned on only during the sampling period to apply the data voltage signal Vdata. For example, the dual gate control circuit 300 may include a ninth switching TFT T9 and a tenth switching TFT T10 that receive the second scan signal Scan2 through a common electrode.

The ninth switching TFT T9 may include a gate electrode connected to the second scan signal Scan2, a first electrode connected to the second node to which the first gate electrode g1 is connected, and a second electrode connected to the second gate electrode g2. The ninth switching TFT T9 may be implemented as the same type as that of the second switching TFT T2 that applies the data voltage signal Vdata, for example, a p-type TFT.

The tenth switching TFT T10 may include a gate electrode connected to the second scan signal Scan2, a first electrode connected to the input line of VDD, and a second electrode connected to the second gate electrode g2. The tenth switching TFT T10 may be implemented as a type opposite to that of the second switching TFT T2 that applies the data voltage signal Vdata, for example, an n-type TFT.

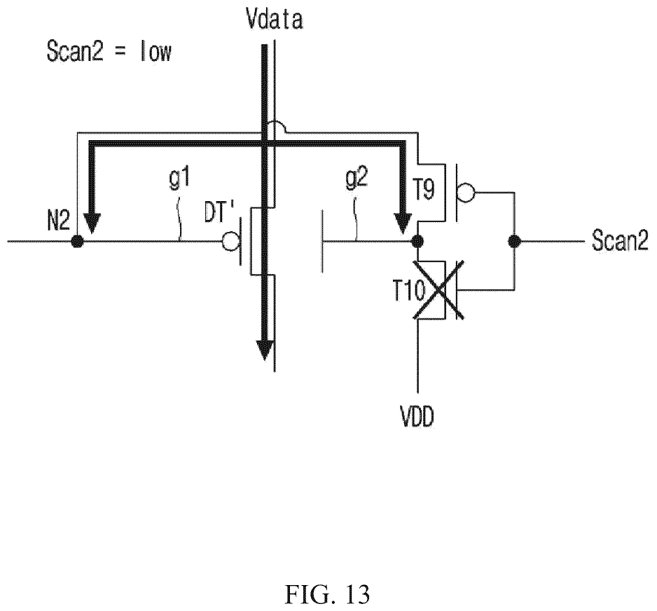

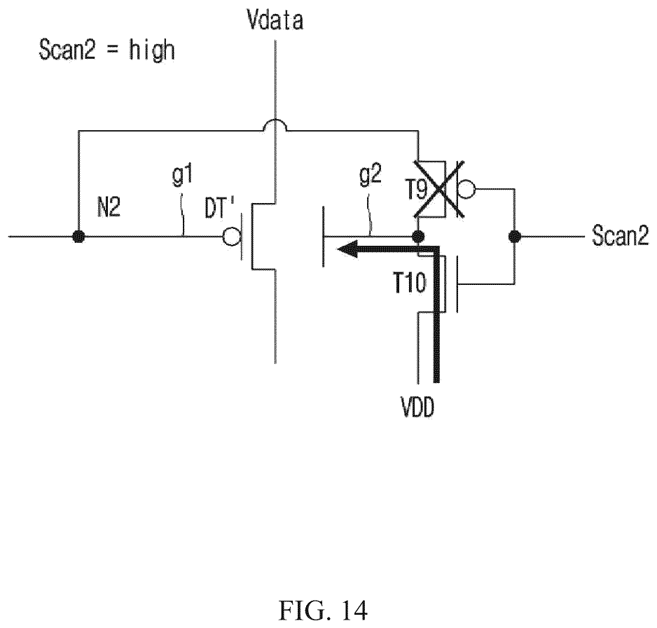

FIG. 13 is a diagram illustrating an operation of the dual gate control circuit 300 when the second scan signal Scan2 is input at a low level, and FIG. 14 is a diagram illustrating an operation of the dual gate control circuit 300 when the second scan signal Scan2 is input at a high level.

Referring to FIG. 13, when the second scan signal Scan2 is input at the low level, the data voltage signal Vdata is applied to the driving TFT DT′. The ninth switching TFT T9 is turned on in response to the second scan signal Scan2 at the low level. The turned-on ninth switching TFT T9 interconnects the second gate electrode g2 and the first gate electrode g1. The tenth switching TFT T10 is turned off when the second scan signal Scan2 at the low level is input.

Referring to FIG. 14, when the second scan signal Scan2 is input at the high level, the tenth switching TFT T10 is turned on. The turned-on tenth switching TFT T10 connects the second gate electrode g2 to the input line of VDD. The ninth switching TFT T9 is turned off when the second scan signal Scan2 at the high level is input.

The subpixel circuit according to the second embodiment of the present disclosure includes the dual gate control circuit 300 that connects the second gate electrode g2 to the first gate electrode g1 so that Vgs of the bottom gate and Vgs of the top gate may be maintained the same as each other when sampling the threshold voltage Vth of the driving TFT DT′, thereby reducing errors occurring when sampling the threshold voltage Vth.

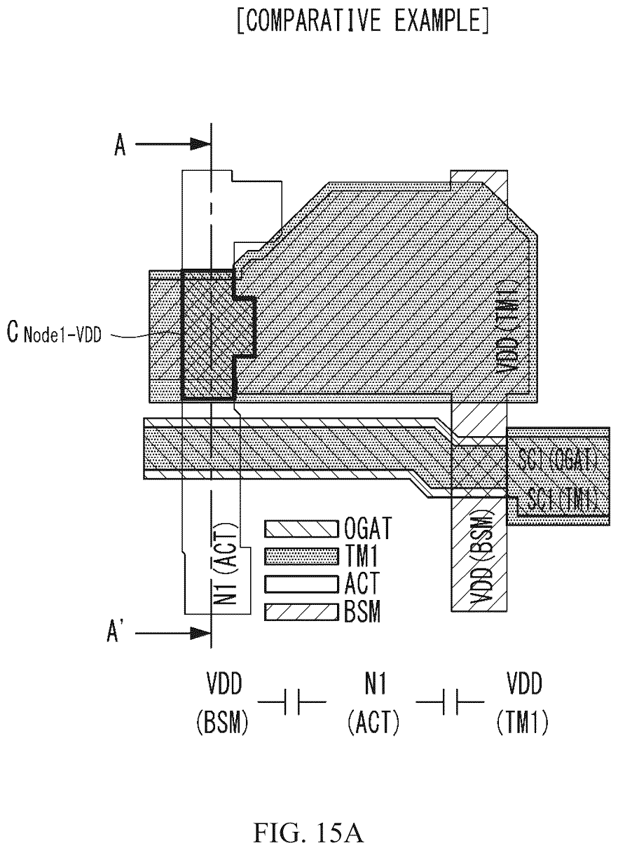

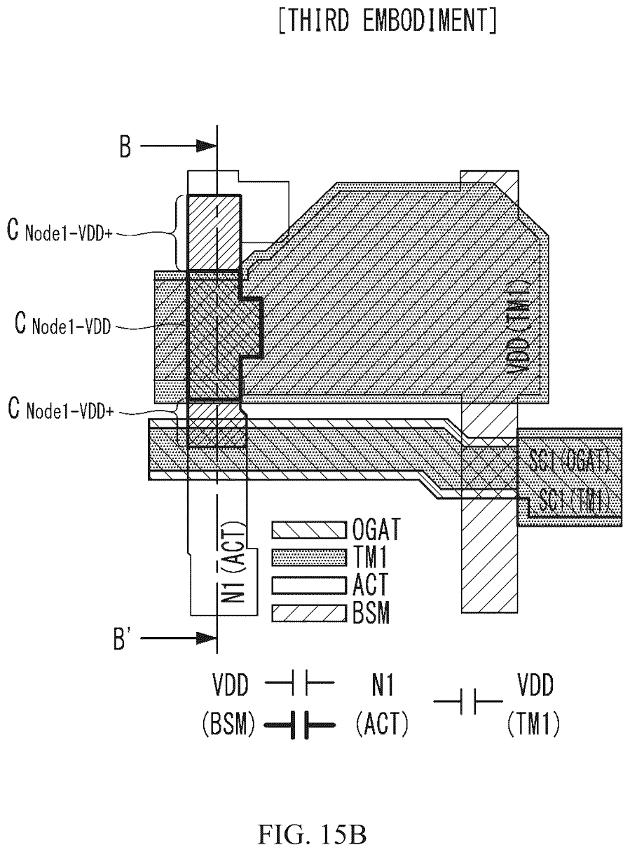

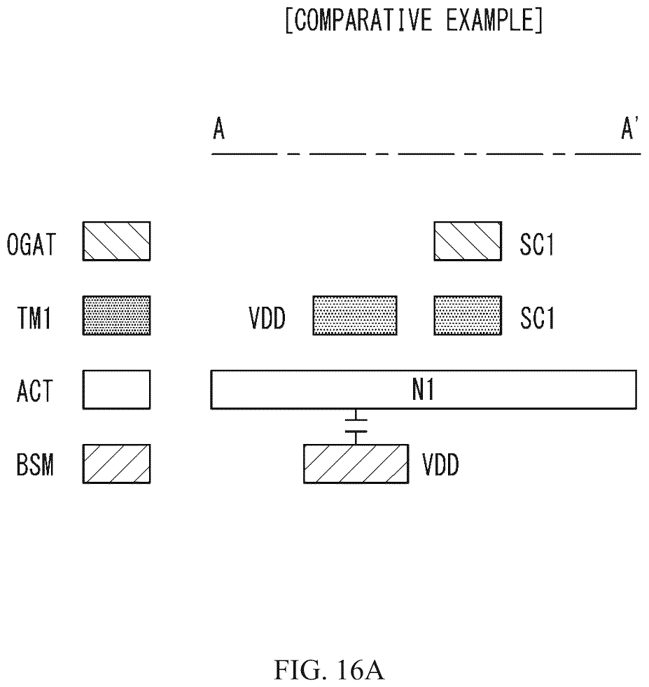

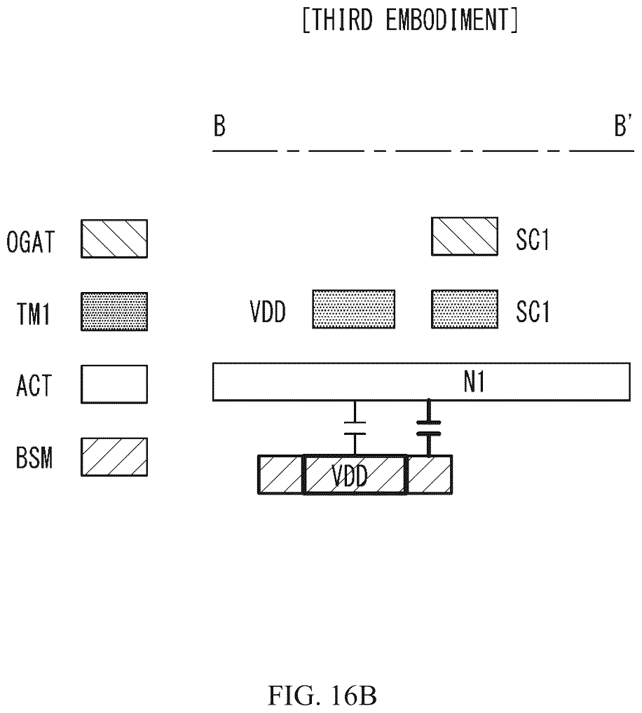

FIGS. 15A, 15B, 16A, and 16B are drawings for describing an error reduction structure of a subpixel according to a third embodiment of the present disclosure. FIG. 15A is a plan view illustrating partial areas of a subpixel according to a comparative example and FIG. 15B is a plan view illustrating partial areas of the subpixel according to the third embodiment of the present disclosure, and each of FIGS. 16A and 16B is a cross-sectional view schematically illustrating a positional relationship between wires of the subpixels according to the comparative example and the third embodiment of FIGS. 15A and 15B, respectively.

The error reduction structure of the subpixel according to the third embodiment of the present disclosure may reduce sampling errors that occur due to change in the voltage of the first node N1 resulting from a kickback phenomenon when the first scan signal Scan1 switches to an off level, i.e., switches from a high state to a low state after sampling the threshold voltage Vth, which has been described in the third case (case 3).

Referring to FIGS. 15A, 15B, 16A, and 16B, in one area of the subpixel according to [Comparative Example], a semiconductor layer ACT is disposed on a light-shielding pattern BSM (Bottom Shield Metal) to which VDD power is applied, a first metal layer TM1 is disposed on the semiconductor layer ACT, and a gate metal layer OGAT is formed on the first metal layer TM1.

The light-shielding pattern BSM includes a VDD pattern, and the semiconductor layer ACT includes the first node N1. In an area where the VDD pattern and the first node N1 overlap, a capacitance CNode1-VDD between the first node N1 and VDD may occur. The first metal layer TM1 includes a VDD line pattern and a first scan line SC1. The gate metal layer OGAT includes the first scan line SC1.

When the voltage applied to the first scan line SC1 formed on the first metal layer TM1 and the first scan line SC1 formed on the gate metal layer OGAT switches from a high state to a low state, the voltage of the first node N1 adjacent thereto may change.

When compared to the structure of the subpixel according to [Comparative Example], in the subpixel according to [Third Embodiment], a VDD pattern formed on the light-shielding pattern BSM has an expanded size+VDD. Accordingly, an area where the VDD pattern and the first node N1 overlap increases by the expanded area+VDD, so that the capacitance between the first node N1 and VDD may increase by the expanded area (C_{Node1-VDD+}). Here, the light-shielding pattern BSM may be extended to an area where the semiconductor active layer LTPS is not formed.

As the capacitance of the first node N1 increases, even when the voltage of the adjacent first scan line SC1 fluctuates, the voltage of the first node N1 may be stably maintained.

The subpixel circuit according to the third embodiment of the present disclosure may increase the size of the VDD pattern adjacent to the first node N1 to increase the capacitance between the first node N1 and VDD, thereby reducing errors occurring when sampling the threshold voltage Vth.

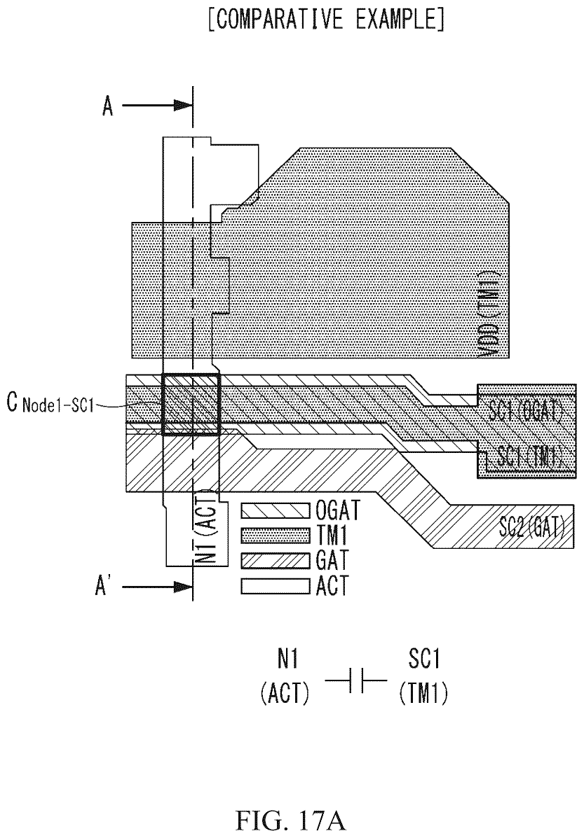

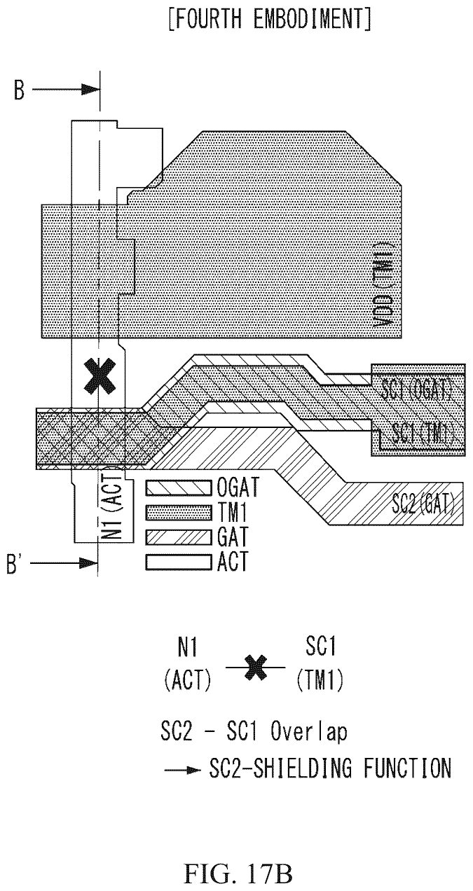

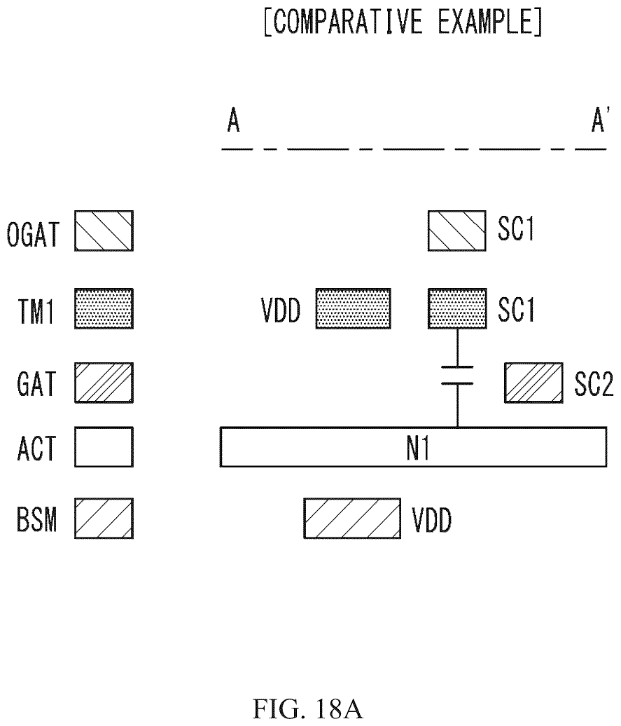

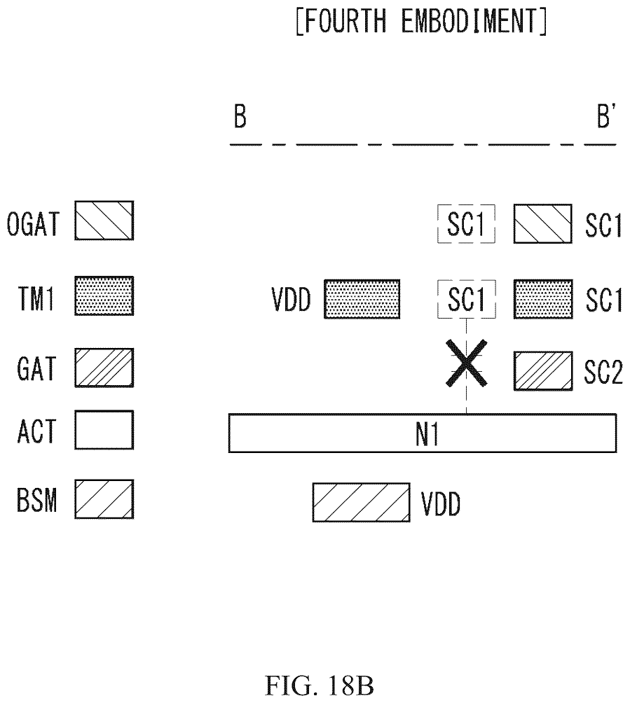

FIGS. 17A, 17B, 18A, and 18B are drawings for describing an error reduction structure of a subpixel according to a fourth embodiment of the present disclosure. FIG. 17A is a plan view illustrating parts of a subpixel according to a comparative example and FIG. 17B is a plan view illustrating parts of the subpixel according to the fourth embodiment of the present disclosure, and each of FIGS. 18A and 18B is a cross-sectional view briefly illustrating a positional relationship between wires of the subpixels of the comparative example and the fourth embodiment of FIGS. 17A and 17B, respectively.

The error reduction structure of the subpixel according to the fourth embodiment of the present disclosure may reduce the sampling error that occurs due to change of the voltage of the first node N1 resulting from the kickback phenomenon when the first scan signal Scan1 is switched to an off level after the threshold voltage Vth is sampled, which has been described in the third case (case 3).

Referring to FIGS. 17A, 17B, 18A, and 18B, in one area of the subpixel according to [Comparative Example], a semiconductor layer ACT, a first gate metal layer GAT, a first metal layer TM1, and a second gate metal layer OGAT may be sequentially positioned on a light-shielding pattern BSM to which VDD power is applied.

The light-shielding pattern BSM includes a VDD pattern, and the semiconductor layer ACT includes a first node N1. The first gate metal layer GAT includes a second scan line SC2, and the first metal layer TM1 includes a VDD line pattern and a first scan line SC1. The second scan line SC2 and the first scan line SC1 may be formed at positions not overlapping each other. The second gate metal layer OGAT includes a first scan line SC1 formed at a position that overlaps the first scan line SC1 of the first metal layer TM1.

In the subpixel according to [Comparative Example], the second scan line SC2 and the first scan line SC1 are formed at positions not overlapping each other. Accordingly, capacitance CNode1-SC1 occurs between the first node N1 and the first scan line SC1 formed in the first metal layer TM1 and the second gate metal layer OGAT. Therefore, when the voltage applied to the first scan line SC1 formed in the first metal layer TM1 and the gate metal layer OGAT switches from a high state to a low state, the voltage of the first node N1 may change due to change in capacitance between the first scan line SC1 and the first node N1.

The subpixel according to [the fourth embodiment] forms the first scan line SC1 and the second scan line SC2 at overlapping positions on the first node N1. Accordingly, the second scan line SC2 and the first scan line SC1 may be sequentially positioned on the first node N1. The capacitance excited between the first node N1 and the first scan line SC1 may be removed by the second scan line SC2 located between the first node N1 and the first scan line SC1. Accordingly, even when the first scan signal Scan1 applied to the first scan line SC1 switches from a high state to a low state and a kickback occurs, the effect of the kickback is shielded by the second scan line SC2, so that the voltage of the first node N1 may be stably maintained.

The subpixel circuit according to the fourth embodiment of the present disclosure may reduce errors occurring during sampling of the threshold voltage Vth by forming the first scan line SC1 to overlap the second scan line SC2 and thereby eliminating the capacitance excited between the first node N1 and the first scan line SC1.

The display device according to the embodiment of the present disclosure may improve accuracy of the operation of the subpixel by applying various error reduction structures that reduce errors occurring during sampling to a subpixel of an internal compensation structure which samples the threshold voltage of the driving TFT and applies a data voltage compensated by the threshold voltage to the gate electrode of the driving TFT.

The effects of the present disclosure are not limited to those illustrated above, and more diverse effects are included within the present disclosure.

Even though the embodiments of the present disclosure have been described in more detail with reference to the attached drawings, the present disclosure is not necessarily limited to these embodiments, and various modifications may be made without departing from the technical spirit of the present disclosure. Accordingly, the embodiments disclosed in the present disclosure are not intended to limit the technical spirit of the present disclosure but to describe the technical spirit, and the scope of the technical spirit of the present disclosure is not limited by these embodiments. Therefore, it should be understood that the embodiments described above are illustrative and not restrictive in all respects. The scope of protection of the present disclosure should be interpreted by the claims, and all technical ideas within a scope equivalent thereto should be interpreted as being included in the scope of rights of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a light emitting element;
a driving transistor comprising a first electrode connected to a first node, a first gate electrode connected to a second node, and a second electrode connected to a third node, and configured to apply a voltage according to a data voltage signal applied to the first node to the second node during a threshold voltage sampling period, generate a driving current according to the voltage applied to the second node using a high-potential voltage applied to the first node during an emission period, and apply the driving current to the third node;
a first switching transistor comprising a gate electrode to which a first scan signal is input, a first electrode connected to the second node, and a second electrode connected to the third node;
a second switching transistor comprising a gate electrode to which a second scan signal is input, a first electrode connected to a data line to which the data voltage signal is applied, and a second electrode connected to the first node; and
a capacitor unit connected between an input line of the high-potential voltage and the second node, wherein the capacitor unit, in operation, stores a data voltage compensated by a threshold voltage,
wherein, in operation, capacitance of the capacitor unit is decreased during the threshold voltage sampling period and is increased during the emission period.

2. The display device according to claim 1, wherein the capacitor unit comprises:
a first capacitor comprising a first electrode connected to the second node and a second electrode connected to a fifth node;
a second capacitor comprising a first electrode connected to the fifth node and a second electrode connected to the input line of the high-potential voltage; and
a first switch configured to interconnect the first capacitor and the second capacitor during the threshold voltage sampling period, and to connect the fifth node to the input line of the high-potential voltage in a period other than the threshold voltage sampling period.

3. The display device according to claim 2, wherein the first switch comprises a gate electrode configured to receive the second scan signal, a first electrode connected to the input line of the high-potential voltage, and a second electrode connected to the fifth node, and the first switch is turned on and off in synchronization with the second switching transistor.

4. The display device according to claim 1, wherein:
the driving transistor comprises a second gate electrode of a bottom gate, and
the display device further comprises a gate control circuit configured to connect the second gate electrode of the driving transistor to the second node during the threshold voltage sampling period.

5. The display device according to claim 4, wherein:
the gate control circuit comprises:
a second switch comprising a gate electrode configured to receive the second scan signal, a first electrode connected to the second node, and a second electrode connected to the second gate electrode of the driving transistor; and
a third switch comprising a gate electrode configured to receive the second scan signal, a first electrode connected to the input line of the high-potential voltage, and a second electrode connected to the second gate electrode of the driving transistor, and
the second switch is turned on and off in synchronization with an on/off operation of the second switching transistor, and the third switch is turned on and off opposite to the on/off operation of the second switching transistor.

6. The display device according to claim 5, wherein:
the second switching transistor comprises a P-type transistor;
the second switch comprises a P-type transistor; and
the third switch comprises an N-type transistor.

7. The display device according to claim 1, wherein:
a semiconductor layer, a first metal layer, and a gate metal layer are sequentially stacked on a light-shielding pattern,
a first pattern configured to apply the high-potential voltage is formed in the light-shielding pattern,
the first node is formed in the semiconductor layer,
a second pattern configured to apply the high-potential voltage and a first metal first scan line pattern configured to transmit the first scan signal are formed in the first metal layer,
a gate metal first scan line pattern is formed in the gate metal layer at a position overlapping the first metal first scan line pattern, and
the first pattern is formed to be extended more than the second pattern.

8. The display device according to claim 7, wherein the first pattern is formed to be extended from the semiconductor layer to an area where an active semiconductor layer is not formed.

9. The display device according to claim 1, wherein:
a semiconductor layer, a first gate metal layer, a first metal layer, and a second gate metal layer are sequentially stacked on a light-shielding pattern,
a first pattern configured to apply the high-potential voltage is formed in the light-shielding pattern,
the first node is formed in the semiconductor layer,
a second scan line pattern configured to apply the first scan signal is formed in the first gate metal layer,
a second pattern configured to apply the high-potential voltage and a first metal first scan line pattern configured to transmit the first scan signal are formed in the first metal layer,
a gate metal first scan line pattern is formed in the second gate metal layer at a position overlapping the first metal first scan line pattern, and
the second scan line pattern, the first metal first scan line pattern, and the gate metal first scan line pattern are formed to overlap in a same area.

10. The display device according to claim 9, wherein the first pattern is formed to be extended more than the second pattern.

11. The display device according to claim 1, wherein each of the driving transistor, the first switching transistor, and the second switching transistor is a thin film transistor (TFT).
